(19) United States
(12) Patent Application Publication
(10) Pub. No.: US 2016/0268219 A1
(43) Pub. Date: Sep. 15, 2016

(54) SEMICONDUCTOR DEVICE

(71) Applicant: KABUSHIKI KAISHA TOSHIBA, Tokyo (JP)

(72) Inventors: Chisato FURUKAWA, Komatsu Ishikawa (JP); Masaaki OGAWA, Sagamihara Kanagawa (JP); Takako MOTAI, Yokohama Kanagawa (JP); Yoko IWAKAJI, Minato Tokyo (JP)

(21) Appl. No.: 14/839,407

(22) Filed: Aug. 28, 2015

(30) Foreign Application Priority Data
Mar. 13, 2015 (JP) 2015-051476

(51) Int. Cl. H01L 23/00; H01L 29/205; H01L 23/29; H01L 21/66; H01L 21/02; H01L 23/31; H01L 29/778; H01L 29/423

(52) U.S. Cl. CPC H01L 23/564; H01L 29/7787; H01L 29/205; H01L 29/42364; H01L 22/12; H01L 21/0217; H01L 21/02271; H01L 23/3135; H01L 23/291; H01L 23/293

(57) ABSTRACT

According to an embodiment, a semiconductor device includes a semiconductor layer, a first insulating layer that has refractive index of 1.95 or less, contains silicon nitride, and located on the semiconductor layer, and a resin that is provided on the first insulating layer and is in contact with the first insulating layer.

### CROSS-REFERENCE TO RELATED APPLICATION

This application is based upon and claims the benefit of priority from Japanese Patent Application No. 2015-051476, filed Mar. 13, 2015, the entire contents of which are incorporated herein by reference.

### FIELD

Embodiments described herein relate generally to a semiconductor device.

### BACKGROUND

In a power semiconductor device such as a HEMT (High Electron Mobility Transistor), a silicon nitride layer is used as a protective layer. The silicon nitride layer is generally formed by a plasma CVD (Chemical Vapor Deposition) method.

A silicon nitride layer formed by plasma CVD may contain hydrogen. When bonded with nitrogen, the hydrogen remains within the silicon nitride layer. In other words, hydrogen bonds with nitrogen, reducing the nitrogen that can be bonded with silicon and the silicon nitride layer becomes a silicon-rich layer, i.e., it contains free silicon atoms.

The silicon-rich silicon nitride layer, however, may be unacceptable because of leakage current flow when a high voltage is applied to the semiconductor device, and by electrochemical reaction occurring upon the intrusion of water or moisture into the device through the silicon rich silicon nitride layer.

### DESCRIPTION OF THE DRAWINGS

FIG. 1A is a schematic cross sectional view illustrating a main portion of a semiconductor device according to the embodiment, and FIG. 1B is a schematic plan view illustrating the main portion of the semiconductor device according to the embodiment.

FIG. 2 is a schematic view for use in describing a water vapor permeability test.

### DETAILED DESCRIPTION

In general, according to one embodiment a semiconductor device includes a semiconductor layer, a first silicon nitride insulating layer having a refractive index of 1.95 or less located on the semiconductor layer, and resin located on the first insulating layer and in contact with the first insulating layer.

Hereinafter, an embodiment will be described with reference to the drawings. In the following description, the same reference numbers refer to the same elements and features and a repeated description thereof is omitted where appropriate.

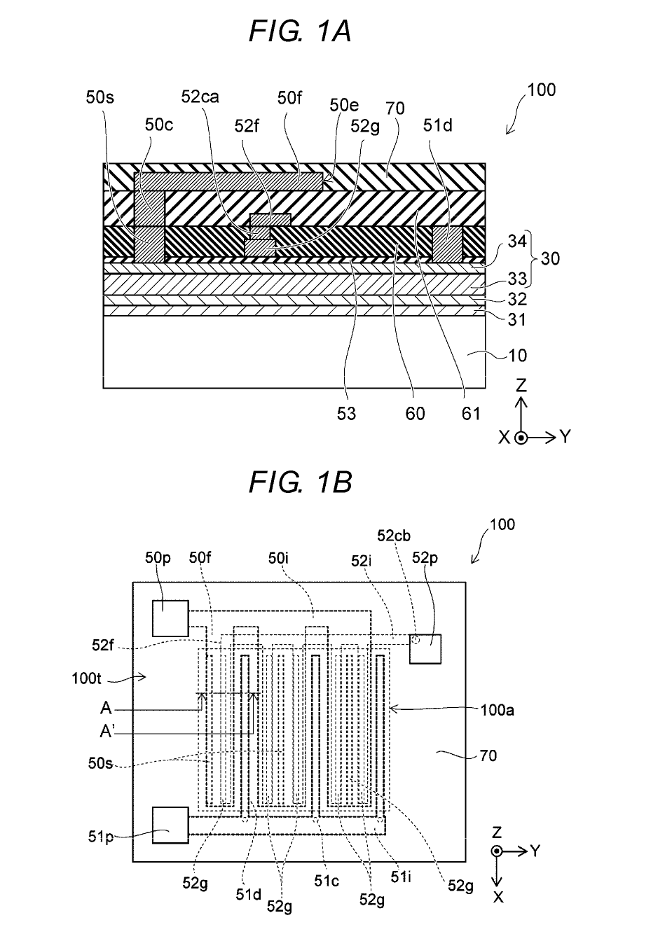

FIG. 1A is a schematic cross sectional view illustrating a main portion of the semiconductor device according to the embodiment. FIG. 1B is a schematic plan view illustrating the main portion of the semiconductor device according to the embodiment.

FIG. 1A illustrates a cross section taken along the line of A-A′ of FIG. 1B.

Further, in the drawings illustrated below, a three dimensional coordinate system is introduced. Here, X axis, Y axis, and Z axis intersect with each other. For example, the X axis, Y axis, and Z axis are all orthogonal to each other.

As a semiconductor device 100 according to the embodiment, a High Electron Mobility Transistor (HEMT) is shown as one example.

The semiconductor device 100 includes, for example, a substrate 10, a first buffer layer 31, a second buffer layer 32, a first nitride semiconductor layer (hereinafter, for example, channel layer 33), a second nitride semiconductor layer (hereinafter, for example, barrier layer 34), a first electrode (hereinafter, for example, a source electrode 50s), a second electrode (hereinafter, for example, drain electrode 51d), a third electrode (hereinafter, for example, gate electrode 52g), a second insulating layer (hereinafter, gate insulating film 53), a protective layer 60, a first insulating layer (hereinafter, protective layer 61), and a resin layer 70. The channel layer 33 and the barrier layer 34 are collectively referred to as a semiconductor layer 30.

The substrate 10 comprises silicon (Si). The substrate 10 materials are not limited to silicon, but may be comprised of sapphire, diamond, silicon carbide, carbon, nitride semiconductor, boron nitride, or germanium.

The first buffer layer 31 is provided on the substrate 10. The first buffer layer 31 includes aluminum nitride. The second buffer layer 32 is provided on the first buffer layer 31. The second buffer layer 32 includes gallium aluminum nitride.

A channel layer 33 is located on the second buffer layer 32. The channel layer 33 includes undoped gallium nitride (GaN), or undoped gallium aluminum nitride (AlₓGa₁₋ₓN where 0≦X<1). The channel layer 33 may include any of GaₓIn₁₋ₓN_{y}As_{1-y} where 0≦x≦1, 0≦y≦1, AlₓIn_{y}Ga_{1-x-y}N (0≦x≦1, 0≦y≦1), and BₓIn₁₋ₓN where 0≦x≦1.

A barrier layer 34 is located on the channel layer 33. The barrier layer 34 includes undoped or n-type gallium aluminum nitride (Al_{y}Ga_{1-y}N where (0<Y≦1, X<Y)). Further, the barrier layer 34 may include any of GaₓIn₁₋ₓN_{y}As_{1-y} where (0≦x≦1, 0≦y≦1), AlₓIn_{y}Ga_{1-x-y}N where (0≦x≦1, 0≦y≦1), and BₓIn₁₋ₓN where (0≦x≦1).

The channel layer 33 and the barrier layer 34 have different crystal lattice constants, and thus strain is induced as a result thereof. This strain induces formation of a two dimensional electron gas (2DEG) in the channel layer 33 in the vicinity of the boundary between the channel layer 33 and the barrier layer 34.

The source electrode 50s is located on the barrier layer 34. As shown in FIG. 1B, a plurality of source electrodes 50s are provided extending in the X direction and spaced from one another in the Y direction. The lowermost ends of the source electrodes 50s are electrically connected to the barrier layer 34, from which they extend through the protective layer 60 and the protective layer 61. Each of the source electrodes 50s forms an ohmic contact with the barrier layer 34. Each of the source electrodes 50s is connected, through a contact electrode 50c, to a field plate electrode 50f. The field plate electrodes 50f of the source electrodes 50s are connected to a source wiring line 50i (FIG. 1B) extending in the Y direction at one end of the source wiring lines 50i. The field plate electrode 50f and the source wiring line 50i are provided over the protective layer 61.

The source wiring line 50i is electrically connected to the source electrode 50s through the field plate electrode 50f and the contact electrode 50c. Each of the field plate electrode 50f (fourth electrode) is provided, for example, over the protective layer 61. A source pad electrode 50p is connected to the source wiring 50i. A portion of the source pad electrode 50p extends outwardly of, or through and terminates at the surface of, the resin layer 70 and thus is exposed within the resin layer 70.

The drain electrode 51d is provided on the barrier layer 34. In the Y direction, a plurality of the drain electrodes 51d extend in the X direction and are spaced apart in the Y direction as shown in FIG. 1B. The drain electrodes 51d are electrically connected to the barrier layer 34. Each of the drain electrodes 51d forms an ohmic contact with the barrier layer 34.

A drain wiring line 51i is located on the protective layer 61, and extends in the Y direction generally parallel to, and at the opposite side of the drain electrodes 51d and the source electrodes 50s from, the source wiring line 50i. The drain wiring 51i is electrically connected to the drain electrodes 51d through individual contact electrodes 51c. A drain pad electrode 51p is connected to the drain wiring 51i. The drain pad electrode 51p extends through the resin layer 70 so that its outermost surface is exposed from, i.e. not covered by, the resin layer 70.

The source electrodes 50s and the drain electrodes 51d extend in the area between the source wiring 50i and the drain wiring 51i. The source electrodes 50s and the drain electrodes 51d extend in the X direction on the barrier layer 34.

The gate insulating film 53 is provided on the barrier layer 34. The gate insulating film 53 extends between the barrier layer 34 and the gate electrodes 52g, but the source electrodes 50s and drain electrodes 51d extend through the gate insulating film 53 to contact the barrier layer 34. The gate insulating film 53 includes any of silicon nitride (Si₃N₄), silicon oxide (SiO₂), and aluminum oxide (Al₂O₃).

The gate electrodes 52g are located ever the barrier layer 34, with the gate insulating film 53 located therebetween. The gate electrodes 52g are located between the source electrodes 50s and the drain electrodes 51d, in the Y direction. A field plate electrode 52f is located on the protective layer 60. A gate wiring line 52i is electrically connected to the gate electrodes 52g through the field plate electrode 52f and a contact electrode 52ca. A gate pad electrode 52p is electrically connected to the gate wiring line 52i through a contact electrode 52cb. The gate pad electrode 52p extends through, and thus the outer surface thereof is exposed from, the resin layer 70.

The number of the source electrodes 50s, drain electrodes 51d, and gate electrodes 52g is not restricted to the illustrated number. The drain electrodes 51d, gate electrodes 52g and source electrodes 50s are interdigited, such that, along the Y direction, the drain electrodes 51d and the source electrodes 50s are alternately arranged in a spaced relationship with respect to one another with a gate electrode 52g located therebetween.

In the semiconductor device 100, the region where the source electrodes 50s, the drain electrodes 51d, and the gate electrodes 52g are arranged is defined as an active region 100a. The area surrounding the active region 100a in the X and Y directions is defined as a termination region 100t.

The protective layer 60 is located over the gate insulating film 53 on the semiconductor layer. The protective layer 60 includes, for example, silicon nitride. The protective layer 61 is located on the protective layer 60. The protective layer 61 is located, in the Y direction, between the source electrode 50s and the gate electrode 52g and between the drain electrode 51d and the gate electrode 52g. The resin layer 70 is provided on the protective layer 61. The protective layer 61 is in contact with the resin layer 70. The substrate 10, the semiconductor layer 30, the buffer layers 31 and 32, the source electrode 50s, the drain electrode 51d, the gate electrode 52g, the gate insulating film 53, the protective layer 60, and the protective layer 61 are sealed by the resin layer 70.

The protective layer 61 includes silicon nitride (SiₓN_{y}), for example Si₃N₄. The protective layer 61 has a refractive index of 1.95 or less. Here, the refractive index of the protective layer 61 varies depending on the composition ratio of Si and N. For example, when the refractive index is 1.95 or less, the silicon nitride layer is rich in nitrogen, and the ratio of Si to (N/(N+Si)) is greater than 0.35; whereas when the refractive index is greater than 1.95, the silicon nitride layer tends to be rich in silicon. The protective layer 61 according to the embodiment is a nitrogen-rich layer, and thus minimal free silicon (Si) is present in the layer.

Further, the thickness of the protective layer 61 (thickness in the Z direction) is greater than the moisture (water or water vapor or other detrimental fluid) intrusion distance in the water vapor permeability test (THB test) performed on the protective layer 61. For example, the thickness of the protective layer 61 is more than 50 nm. Here, the moisture intrusion distance is the depth of the moisture intrusion from the upper surface to the lower surface of the protective layer 61 after the water vapor permeability test is performed on the protective layer 61. The water vapor permeability test will be described later.

The protective layer 61 is formed, for example, by plasma CVD. Here, the source gas for forming the protective layer 61 is SiH₂Cl₂ and NH₄.

Further, in the boundary between the gate insulating film 53 and the protective layer 60 and the boundary between the protective layer 60 and the protective layer 61, oxygen is outgassed, i.e., released, after forming the respective layers. By analyzing the oxygen, for example, using a SIMS, the boundary between the gate insulating film 53 and the protective layer 60 and the boundary between the protective layer 60 and the protective layer 61 may be recognized.

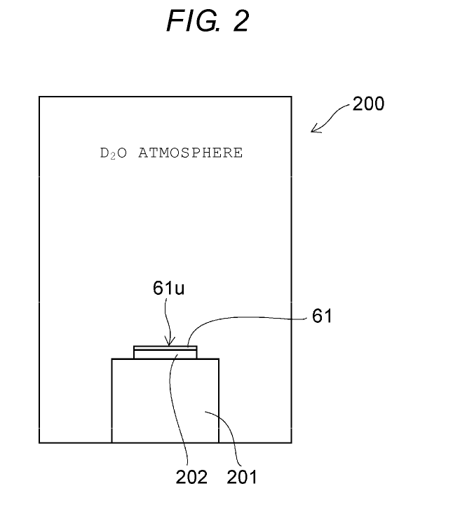

FIG. 2 is a schematic view for use in describing the water vapor permeability test.

For example, to perform the water vapor permeability test, a substrate 202 having the protective layer 61 film thereon formed as described above is placed on a stage 201 of an airtight chamber 200. Bias is applied to the protective layer 61 and water vapor is introduced into the chamber. A heavy water vapor gas, such as deuterium oxide (D₂O) is used as the water vapor for the test. The film thickness of the protective layer 61 is, for example, several hundred nm thick.

When a SIMS analysis of deuterium (D) is performed on the protective layer 61 tested by the water vapor permeability test, it is found that the moisture intrusion distance of the heavy water from the top surface 61u of the protective layer 61 as a result of the test is 50 nm or less. Accordingly, by making the protective layer 61 thicker than 50 nm, it is found that moisture intrusion from the upper exposed side of the protective layer 61 to the lower side of the protective layer 61 adjacent the protective layer 60 may be reliably prevented.

On the other hand, a nitride silicon layer with the refractive index of more than 1.95 contains excess hydrogen (H). Here, the hydrogen, bonding with nitrogen, remains within the silicon nitride layer. Accordingly, when the amount of the nitrogen that may be bonded with the silicon is relatively reduced, the silicon nitride layer becomes a silicon-rich layer and its refractive index n becomes higher (n>1.95).

A silicon nitride layer with the refractive index of more than 1.95 is deteriorated in terms of film quality because of leakage current flow occurring upon the application of a high voltage, and electrochemical reaction occurring as a result of the intrusion of water or moisture thereinto. For example, when oxygen in water reacts with silicon, silicon oxide is formed within the silicon nitride layer, the silicon oxide may forma gel, or the silicon nitride layer may be broken or cracked at a starting point of the silicon oxide.

The moisture or water intrusion distance into a silicon nitride layer with the refractive index of more than 1.95 becomes more than 50 nm in the above described water vapor permeability test. It is found that the moisture penetration resistance of a silicon nitride layer with a refractive index of more than 1.95 is less than the moisture or water penetration resistance of a silicon nitride layer with a refractive index of 1.95 or less.

The protective layer 61 according to the embodiment has a refractive index of 1.95 or less and the protective layer 61 is rich in nitrogen. In short, almost all silicon atoms within the protective layer 61 are bonded with nitrogen. Even when a high voltage is applied to this protective layer 61, the insulation property of the protective layer 61 is improved and very low leakage current flows. For example, the distal end 50e of the field plate electrode 50f is located over the protective layer 61 at a position the Z direction between an underlying gate electrode 52g and drain electrode 51d. Accordingly, when a voltage is applied between the field plate electrode 50f and the drain electrode 51d, an electric field is also applied to the protective layer 61. Even if this electric field is applied, the protective layer 61 has a high dielectric breakdown value.

In the protective layer 61 according to the embodiment, the moisture or water intrusion distance is more than 50 nm. Owing to this, the intrusion of the moisture or water through the protective layer 61 is suppressed. That is, electrochemical reaction between the protective layer 61 and oxygen minimally occurs. As the result, the protective layer 61 is not broken or cracked.

Further, the semiconductor device 100 sealed by the resin layer 70 is less expensive than a hermetically sealed semiconductor device.

Further, in the embodiment, the semiconductor device may include a MOSFET, IGBT, and FWD, other than the HEMT.

In the embodiment, “on” in the case of the expression of “A is located on B” means the case where “A is in contact with B and upper than B” as well as the case where “A is not in contact with B but just upper than B”. Further, the expression of “A is located on B” is also applied to the case where A is under B with A and B inverted and the case where A and B are arranged alongside on another. This is because even if rotating the semiconductor device according to the embodiment, the structure of a semiconductor device does not change before and after the rotation.

As mentioned above, the embodiment has been described with reference to the specific example. The embodiment is not restricted to the above example. In other words, modifications properly made by those skilled in the art are to be included in the scope of the embodiment as far as they have the characteristics of the embodiment. Each element contained in each specific example as mentioned above and its position, material, condition, shape, and size are not restricted to the illustrated ones but may be properly changed.

Further, each element contained in the above mentioned embodiment may be properly combined with each other as far as technically permitted and their combination is to be included in the scope of the embodiment as far as it has the characteristics of the embodiment. Other, within the spirit of the embodiment, various changes and modifications may be easily arrived at by those skilled in the art, and it should be noted that all such changes and modifications should be within the scope of the embodiment.

Further, in the specification, “nitride semiconductor” is intended to include all the semiconductors with the composition ratio of x, y, and z varied within each range in the chemical formula BₓIn_{y}Al_{z}Ga_{1-x-y-z}N, where 0≦x≦1, 0≦y≦1, 0≦z≦1, x+y+z≦1. Further, in the above chemical formula, it should be noted that the compound further including the V group element other than N (nitrogen), the compound further including various doped elements in order to control the various physical property such as conductivity, and the compound further including various elements not intended may be included in “nitride semiconductor”.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor layer;
a first insulating layer comprising silicon nitride and having a refractive index of 1.95 or less located on the semiconductor layer; and
a resin layer located on and contacting the first insulating layer.

2. The device according to claim 1, wherein
the thickness of the first insulating layer is greater than a moisture intrusion distance into the first insulation layer in a water vapor permeability test performed on the first insulating layer.

3. The device according to claim 1, wherein
the first insulating layer is thicker than 50 nm.

4. The device according to claim 1, wherein
the semiconductor layer includes
a first nitride semiconductor layer;
a second nitride semiconductor layer located on the first nitride semiconductor layer, the device further comprising:
a first electrode located on the second nitride semiconductor layer and electrically connected to the second nitride semiconductor layer;
a second electrode located on the second nitride semiconductor layer and electrically connected to the second nitride semiconductor layer; and
a third electrode located on the second nitride semiconductor layer between the first electrode and the second electrode.

5. The device according to claim 4, wherein
the first insulating layer is located between the first electrode and the third electrode and between the second electrode and the third electrode.

6. The device according to claim 4, further comprising:
a second insulating layer located between the semiconductor layer and the third electrode, wherein
the first insulating layer is located on the second insulating layer.

7. The device according to claim 4, further comprising:
a fourth electrode electrically connected to the first electrode and located on the first insulating layer, wherein
the distal end of the fourth electrode is located between the second electrode and the third electrode.

8. The device according to claim 1, wherein in the first insulating layer comprising silicon nitride the ratio of Si to (N/(N+Si)) is greater than 0.35.

9. A method of protecting a semiconductor device from moisture, comprising:
forming a silicon nitride layer having a refractive index equal to or less than 1.95 on the semiconductor device; and
covering the silicon nitride layer with a resin.

10. The method of claim 9, wherein the semiconductor device comprises at least one nitride semiconductor.

11. The method of claim 10, wherein the nitride semiconductor comprises at least one of B, In, Ga, Al and N.

12. The semiconductor device of claim 11, wherein the nitride semiconductor comprises BₓIn_{y}Al_{z}Ga (_{1-x-y-z})N, where 0≦x≦1, 0≦y≦1, 0≦z≦1, x+y+z≦1.

13. The method of claim 9, wherein the silicon nitride layer is formed by chemical vapor deposition using SiH₂Cl₂ and NH₄.

14. The method of claim 9, wherein the semiconductor device is a power semiconductor device.

15. The method of claim 9, wherein the silicon nitride layer has a thickness greater that a moisture penetration depth into the silicon nitride layer occurring in a water vapor permeability test.

16. The method of claim 15, wherein the water vapor used in the water vapor permeability test is deuterium oxide (D₂O).

17. A semiconductor device comprising:
a semiconductor layer;
a first insulating layer comprising a silicon nitride layer located on the semiconductor layer, wherein the ratio of Si to (N/(N+Si)) in the silicon nitride layer is greater than 0.35; and
a resin layer located on and contacting the first insulating layer.

18. The device according to claim 17, wherein
the first insulating layer is thicker than 50 nm.

19. The device according to claim 17, wherein
the first insulating layer has a refractive index less than or equal to 1.95.

20. The device according to claim 17, wherein the semiconductor layer comprises a power semiconductor device.
